(19) United States
(12) Patent Application Publication
(10) Pub. No.: US 2008/0107166 A1
(43) Pub. Date: May 8, 2008

(54) ADAPTIVE EQUALIZER AND ADAPTIVE EQUALIZATION METHOD

(75) Inventor: Cheol-hee LEE, Seoul (KR)

Correspondence Address: STEIN, MCEWEN & BUI, LLP, 1400 EYE STREET, NW, SUITE 300, WASHINGTON, DC, 20005, US

(73) Assignee: Samsung Electronics Co., Ltd., Suwon-si (KR)

(21) Appl. No.: 11/746,882

(22) Filed: May 10, 2007

(30) Foreign Application Priority Data
Nov. 6, 2006 (KR) 2006-108832

(51) Int. Cl. H03H 7/30

(52) U.S. Cl. 375/232; 375/E07.193

(57) ABSTRACT

An adaptive equalizer including n filters in parallel with one another to output signals generated from filtered input data; n error generation units, in parallel with one another, to respectively generate errors with respect to the signals output from the n filters; n filter coefficient update units, in parallel with one another, to respectively update filter coefficients of the n filters using the errors output from the n error generation units and the data input to the n filters; and a clock divider to divide a clock signal by n and to provide the n-divided clock signals having different phases to the n filters, the n error generation units, and the n filter coefficient update units, wherein n is a natural number equal to or greater than 2.

### CROSS-REFERENCE TO RELATED APPLICATION

This application claims the benefit of Korean Patent Application No. 2006-108832, filed on Nov. 6, 2006 in the Korean Intellectual Property Office, the disclosure of which is incorporated herein in its entirety by reference.

### BACKGROUND OF THE INVENTION

1. Field of the Invention

Aspects of the present invention relate to an adaptive equalizer, and, more particularly, to an adaptive equalizer using a Least Mean Square (LMS) algorithm and an adaptive equalization method for use with the adaptive equalizer.

2. Description of the Related Art

An equalizer compensates for a distorted signal. An adaptive equalizer compensates for a distorted signal by adaptively updating equalizer coefficient values according to channel characteristics every clock cycle. The adaptive equalizer may be applied to various receivers, hard disk drives (HDDs), and optical disk drives (ODDs) using a Partial Response Maximum Likelihood (PRML) technique. However, in response to increases in data rates between transmitters and receivers and increases in the reproduction rates of hard disks and optical disks, adaptive equalizers that compensate for distortion of a high speed signal have been suggested. To this end, an adaptive equalizer using a Least Mean Square (LMS) algorithm compensates for distortion of a signal input at a high speed by reducing the amount of computation required to update equalizer coefficient values.

FIG. 1 is a block diagram of a conventional adaptive equalizer using a LMS algorithm. As shown in FIG. 1, the conventional adaptive equalizer includes a filter 101, an error generator 102, and a filter coefficient update unit 103. The filter 101 includes a Finite Impulse Response (FIR) filter that is illustrated in FIG. 2. As illustrated in FIG. 2, if data is input in synchronization with a system clock, the filter 101 multiplies the input data by i updated filter coefficient values (Cₖ₊₁)₁, . . . , (Cₖ₊₁)ᵢ that are input from the filter coefficient update unit 103 every clock cycle. The filter 101 obtains a value of the sum of the product of each tap and outputs the value as an output Eq_out of the adaptive equalizer.

The error generator 102 detects the difference between the output Eq_out of the filter 101 and a pre-set reference value every system clock cycle, and outputs the difference as an error. The output error is transmitted to the filter coefficient update unit 103.

The filter coefficient update unit 103 updates filter coefficient values every system clock cycle based on the LMS algorithm using data input from the filter 101 and the error generator 102. That is, the filter coefficient update unit 103 updates filter coefficient values using Equation 1 below.

Cₖ₊₁=Cₖ+2 μεₖXₖ (K=0,1,2, . . . ) (1)

Here, C denotes a filter coefficient, Cₖ denotes the previous filter coefficient, Cₖ₊₁ denotes the current filter coefficient, μ denotes a gain constant which was set previously according to a channel state, ε denotes an estimated error, which is a value output from the error generator 102, and X denotes input data. The LMS algorithm increases the Signal to Noise Ratio (SNR) by minimizing ε.

However, since the adaptive equalizer using the LMS algorithm illustrated in FIG. 1 must perform computations to update the filter coefficient values every system clock cycle, an ability to conduct high-speed processing of input data is limited. Thus, if the data rate of data input to the adaptive equalizer is too fast to allow computation for updating filter coefficient values, the adaptive equalizer may malfunction.

### SUMMARY OF THE INVENTION

Aspects of the present invention provide an adaptive equalizer using a Least Mean Square (LMS) algorithm to correctly update filter coefficient values by operating adaptively to high speed input data, and an adaptive equalization method for use with the adaptive equalizer.

According to an aspect of the present invention, there is provided an adaptive equalizer comprising: n filters in parallel with one another to output signals generated from filtered input data; n error generation units, in parallel with one another, to respectively generate errors with respect to the signals output from the n filters; n filter coefficient update units, in parallel with one another, to respectively update filter coefficients of the n filters using the errors output from the n error generation units and the data input to the n filters; and a clock divider to divide a clock signal by n and to provide the n-divided clock signals having different phases to the n filters, the n error generation units, and the n filter coefficient update units, wherein n is a natural number equal to or greater than 2.

Each of the n filter coefficient update units may comprise: a first filter coefficient update part to update filter coefficients of the n filters using errors output from the n error generation units and data input to the n filters, respectively; and a second filter coefficient update unit to update a filter coefficient of a corresponding filter among the n filters using a result obtained by adding the updated filter coefficients of the n filters.

According to another aspect of the present invention, there is provided an adaptive equalization method comprising: parallel-filtering of input data; parallel-generating of errors between the parallel-filtered results and a reference value; and parallel-updating of filter coefficients using the parallel-generated errors and the input data before the parallel-filtering is performed, wherein each of the parallel-filtering, the parallel-generating, and the parallel-updating are performed using n-divided clock signals having different phases.

Additional and/or other aspects and advantages of the invention will be set forth in part in the description which follows and, in part, will be obvious from the description, or may be learned by practice of the invention.

### BRIEF DESCRIPTION OF THE DRAWINGS

These and/or other aspects and advantages of the invention will become apparent and more readily appreciated from the following description of the embodiments, taken in conjunction with the accompanying drawings of which:

FIG. 1 is a block diagram of a conventional adaptive equalizer using a Least Mean Square (LMS) algorithm;

FIG. 2 is a circuit diagram of a filter included in the adaptive equalizer illustrated in FIG. 1;

FIG. 3 is a block diagram of an adaptive equalizer according to an embodiment of the present invention;

FIG. 4 is a circuit diagram of a filter included in the adaptive equalizer illustrated in FIG. 3;

FIG. 5 is a block diagram of a filter coefficient update unit included in the adaptive equalizer illustrated in FIG. 3;

FIG. 6 is a circuit diagram of a second filter coefficient update part included in the filter coefficient update unit illustrated in FIG. 5;

FIG. 7 is a circuit diagram of a second filter coefficient update part included in the filter coefficient update unit illustrated in FIG. 5;

FIG. 8 is a flowchart illustrating an adaptive equalization method according to another embodiment of the present invention; and

FIG. 9 is a flowchart illustrating a process of parallel-updating filter coefficients in the method illustrated in FIG. 8.

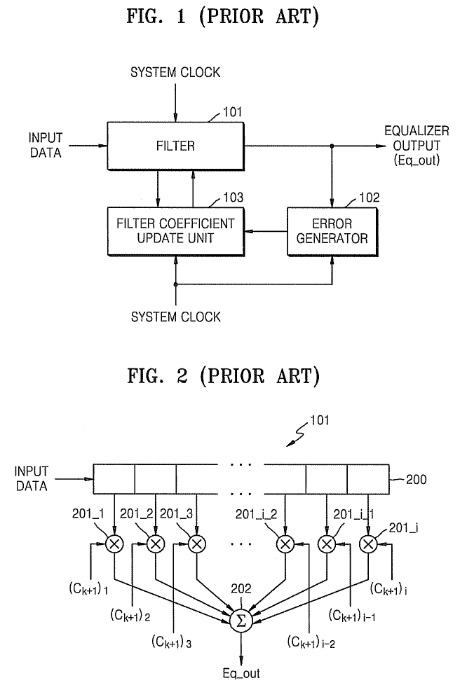

### DETAILED DESCRIPTION OF THE EMBODIMENTS

Reference will now be made in detail to the present embodiments of the present invention, examples of which are illustrated in the accompanying drawings, wherein like reference numerals refer to the like elements throughout. The embodiments are described below in order to explain the present invention by referring to the figures.

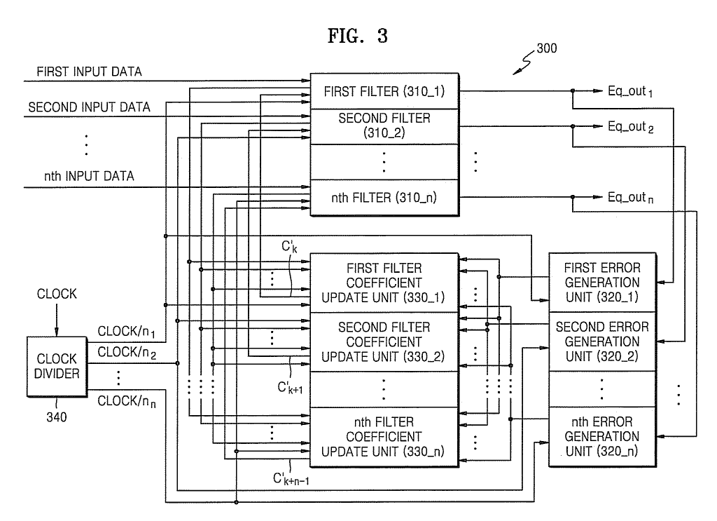

FIG. 3 is a block diagram of an adaptive equalizer 300 according to an embodiment of the present invention. As shown in FIG. 3, the adaptive equalizer 300 includes first through nth filters 310_1 through 310_{—}n that are arranged in parallel with each other, first through nth error generation units 320_1 through 320_{—}n that are arranged in parallel with each other, first through nth filter coefficient update units 330_1 through 330_{—}n that are arranged in parallel with each other, and a clock divider 340. Thus, the adaptive equalizer 300 may be defined as an adaptive equalizer operating with n paths.

Each of the first through nth filters 310_1 through 310_{—}n includes a Finite Impulse Response (FIR) filter. When input data is input to the first through nth filters 310_1 through 310_{—}n in synchronization with a clock provided by the clock divider 340, the first through nth filters 310_1 through 31_{—}n respectively multiply the input data by updated filter coefficient values provided by the first through nth filter coefficient update units 330_1 through 330_{—}n at every tap, every clock cycle. Each of the first through nth filters 310_1 through 310_{—}n adds the product of every tap and outputs the result of the addition.

That is, if first input data is input to the first filter 310_1 in synchronization with a clock (clock/n₁) provided by the clock divider 340, the first filter 310_1 multiplies the first input data by an updated filter coefficient value provided by the first filter coefficient update unit 330_1 at every tap, every clock cycle. The first filter 310_1 adds the product of every tap and outputs the result of the addition as an output signal Eq_outₙ of the adaptive equalizer 300.

If nth input data is input to the nth filter 310_{—}n in synchronization with a clock (clock/nₙ) provided by the clock divider 340, the nth filter 310_{—}n multiplies the nth input data by an updated filter coefficient value provided by the nth filter coefficient update unit 330_{—}n at every tap at every clock cycle. The nth filter 310_{—}n adds the products of every tap and outputs the adding result as an output signal Eq_outₙ of the adaptive equalizer 300.

The first through nth input data is input in parallel. The n output signals Eq_outₙ through Eq_outₙ of the adaptive equalizer 300 are output in parallel. Lines through which the first through nth input data are input and lines through which the n output signals Eq_out₁ through Eq_outₙ are output can be defined as paths.

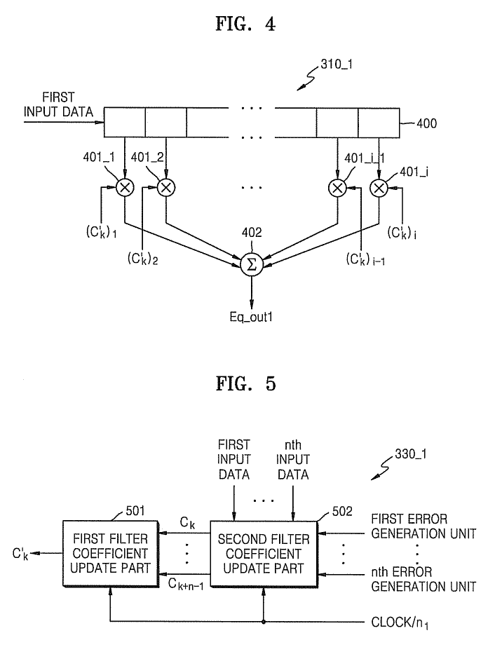

Each of the first through nth filters 310_1 through 310_{—}n can be configured as illustrated in FIG. 4. FIG. 4 is a circuit diagram of the first filter 310_1 according to an embodiment of the present invention. Referring to FIG. 4, the first filter 310_1 includes an I-shift register 400, i multipliers 401_1 through 401_{—}i, and an adder 402.

The shift register 400 shifts the first input data by 1 in synchronization with the clock (clock/n₁) when the first input data is input. The multipliers 401_1 through 401_{—}i respectively multiply signals output from the shift register 400 by updated filter coefficient values (Cₖ′)₁ through (Cₖ′)ᵢ that are provided by the first filter coefficient update unit 330_1. The adder 402 adds the values output from the first through ith multipliers 401_1 through 401_{—}i. The resulting output from the adder 402 is the output signal Eq_out₁ of the first filter 310_1. The output signal Eq_out₁ of the first filter 310_1 is an equalizer output, which is output through the path of the adaptive equalizer 300 in parallel with the n other filters.

The first filter 310_1 transmits the first input data to the first filter coefficient update unit 330_1. The first filter 310_1 may further include a delay (not shown) to delay the transmission of the first input data to the first filter coefficient update unit 330_1 based on the time taken to process the first input data in the first filter 310_1 and the first error generation unit 320_1.

Referring back to FIG. 3, the first through nth error generation units 320_1 through 320_{—}n respectively generate errors with respect to signals output from the first through nth filters 310_1 through 310_{—}n every clock cycle using the LMS algorithm. That is, the first error generation unit 320_1 calculates a difference between the signal Eq_out₁ output from the first filter 310_1 and a pre-set reference value in synchronization with the clock (clock/n₁) provided by the clock divider 340. The calculated difference is output as an error with respect to the signal Eq_out₁ output from the first filter 310_1. The nth error generation unit 320_{—}n calculates a difference between the signal Eq_outₙ output from the first filter 310_{—}n and the pre-set reference value in synchronization with the clock (clock/nₙ) provided by the clock divider 340. The calculated difference is output as an error with respect to the signal Eq_outₙ output from the nth filter 310_{—}n. The pre-set reference value of the first through nth error generation units 320_1 through 320_{—}n may be a constant or may be updated according to a channel state.

The first through nth filter coefficient update units 330_1 through 330_{—}n respectively update filter coefficient values of the first through nth filters 310_1 through 310_{—}n using the first through nth input data transmitted from the first through nth filters 310_1 through 310_{—}n and errors output from the first through nth error generation units 320_1 through 320_{—}n according to the LMS algorithm. Of course, it is understood that, according to an embodiment of the invention, the first through nth input data may be directly input to the first through nth filter coefficient update units 330_1 through 330_{—}n without having to pass through the first through nth filters 310_1 through 310_{—}n.

The first filter coefficient update unit 330_1 updates a filter coefficient value of the first filter 310_1 using the first through nth input data and the errors output from the first through nth error generation units 320_1 through 320_{—}n, in synchronization with the clock (clock/n₁) provided by the clock divider 340, and outputs the filter coefficient value updated in synchronization with the clock (clock/n₁) to the first filter 310_1. That is, the first filter coefficient update unit 330_1 updates filter coefficient values of the first through nth filters 310_1 through 310_{—}n using the first through nth input data and the errors output from the first through nth error generation units 320_1 through 320_{—}n, adds the updated filter coefficient values of the first through nth filters 310_1 through 310_{—}n, and updates the filter coefficient value of the first filter 310_1 using the adding result.

If the number of taps of the first filter 310_1 is i, the first filter coefficient update unit 330_1 provides i updated filter coefficient values to the first filter 310_1. In order to provide the i updated filter coefficient values, the first filter coefficient update unit 330_1 has a number of paths corresponding to the number of taps. That is, if the number of taps of the first filter 310_1 is i, the first filter coefficient update unit 330_1 has i processing paths to allow for an updating of filter coefficient values.

The first filter coefficient update unit 330_1 may be configured as illustrated in FIG. 5, which is a block diagram of the first filter coefficient update unit 330_1. As shown in FIG. 5, the first filter coefficient update unit 330_1 includes a first filter coefficient update part 501 and a second filter coefficient update part 502.

The first filter coefficient update part 501 updates filter coefficient values of the first through nth filters 310_1 through 310_{—}n by applying the LMS algorithm to the first through nth input data and the errors output from the first through nth error generation units 320_1 through 320_{—}n in synchronization with the clock (clock/n₁) provided by the clock divider 340. That is, the first filter coefficient update part 501 updates filter coefficient values of the first through nth filters 310_1 through 310_{—}n using Equation 2.

Cₖ=Cₖ₋ₙ+2 μεₖ₋ₙXₖ₋ₙ (k=n, 2n, 3n, . . . )

Cₖ₊₁=Cₖ₋ₙ₊₁+2 μεₖ₋ₙ₊₁Xₖ₋ₙ₊₁ (k=n, 2n, 3n, . . . ) (2)

Cₖ₊ₙ₋₂=Cₖ₋₂+2 μεₖ₋₂Xₖ₋₂ (k=n, 2n, 3n, . . . )

Cₖ₊ₙ₋₁=Cₖ₋₁+2 μεₖ₋₁Xₖ₋₁ (k=n, 2n, 3n, . . . )

Here, Cₖ denotes an updated filter coefficient value of the first filter 310_1, Cₖ₊₁ denotes an updated filter coefficient value of the second filter 310_2, and Cₖ₊ₙ₋₁ denotes an updated filter coefficient value of the nth filter 310_{—}n. As illustrated in Equation 2, a filter coefficient value of each of the first through nth filters 310_1 through 310_{—}n increases by multiples of n.

The second filter coefficient update part 502 adds n updated filter coefficient values input from the first filter coefficient update part 501 using at least one adding stage. The second filter coefficient update part 502 updates a filter coefficient value of the first filter 310_1 based on the result of the addition. Thus, a filter coefficient value Cₖ′ output from the second filter coefficient update part 502 is an updated filter coefficient value to be provided to the first filter 310_1.

According to an embodiment of the invention, the second filter coefficient update part 502 may be configured as illustrated in FIG. 6 although other configurations are possible. FIG. 6 is a circuit diagram of the second filter coefficient update part 502 according to an embodiment of the present invention. As shown in FIG. 6, the second filter coefficient update part 502 includes a first adding stage 610 and a second adding stage 620.

The first adding stage 610 includes a number of adders equal to ½ the number of updated filter coefficient values input from the first filter coefficient update part 501. Thus, each of first through (n/2)th adders 610_1 through 610_(n/2) included in the first adding stage 610 adds 2 updated filter coefficient values input from the first filter coefficient update part 501. The first adding stage 610 divides the n updated filter coefficient values input from the first filter coefficient update part 501 into two groups based on the updated sequence and adds every two updated filter coefficient values in the same sequence in the two groups.

For example, the first adder 610_1 adds the first updated filter coefficient value Cₖ in the first group and the first updated filter coefficient value C_{k+(n/2+1)} in the second group, and the (n/2)th adder 610_(n/2) adds the last updated filter coefficient value C_{k+(n/2-1)} in the first group and the last updated filter coefficient value Cₖ₊ₙ₋₁ in the second group.

However, the correlation between the updated filter coefficient values to be added may be set differently. For example, the first adder 610_1 may add the first updated filter coefficient value Cₖ and the second updated filter coefficient value Cₖ₊₁. The first adder 610_1 also may be configured to add at least three updated filter coefficient values.

The second adding stage 620 includes only a single adder 621. Thus, the second adding stage 620 adds all sums input from the first adding stage 610. The second adding stage 620 provides the sum Cₖ′ as an updated filter coefficient value of the first filter 310_1. If the number of taps of the first filter 310_1 is i as described above, in order to generate i sums (Cₖ′)₁ through (Cₖ′)ᵢ, the first filter coefficient update unit 330_1 includes i first filter coefficient update parts 501 and i second filter coefficient update parts 502.

When the second filter coefficient update part 502 is configured as illustrated in FIG. 6, an initial filter coefficient value C used by the first filter coefficient update part 501 is set to 1/n of an initial filter coefficient value of a serial structure.

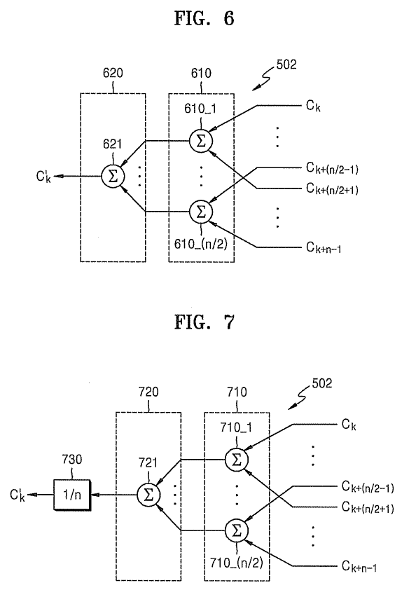

The second filter coefficient update part 502 may be configured as illustrated in FIG. 7. FIG. 7 is a circuit diagram of the second filter coefficient update part 502 according to another embodiment of the present invention. The second filter coefficient update part 502 illustrated in FIG. 7 further comprises a divider 730 arranged alongside first and second adding stages 710 and 720 which are similar to those illustrated in FIG. 6. The first and second adding stages 710 and 720 operate similarly to the first and second adding stages 610 and 620 illustrated in FIG. 6. The divider 730 divides the adding result output from the second adding stage 720 by n and uses the division result to update a filter coefficient value of the first filter 310_1. That is, the division result is an updated filter coefficient value provided to the first filter 310_1.

Referring back to FIG. 5, the second filter coefficient update part 502 may be implemented with only one adder. That is, the second filter coefficient update part 502 may be implemented using a single adder to add the n updated filter coefficient values input from the first filter coefficient update part 501. Here, if the initial filter coefficient value C used by the first filter coefficient update part 501 is not set to 1/n of the initial filter coefficient value of a serial structure, the second filter coefficient update part 502 further includes a divider to divide the result of the addition by n.

Referring back to FIG. 3, the clock divider 340 divides the system clock signal by n and provides the n-divided clock signals (clock/n₁) through (clock/nₙ) having different phases to the first through nth filters 310_1 through 310_{—}n, the first through nth error generation units 320_1 through 320_{—}n, and the first through nth filter coefficient update units 330_1 through 330_{—}n.

FIG. 3 shows the case of an adaptive equalizer with parallel adaptive equalization outputs to allow for data input in parallel. However, the adaptive equalizer illustrated in FIG. 3 can be modified to an adaptive equalizer further including a serial-to-parallel converter, which converts serial input data to parallel data, and a parallel-to-serial converter, which converts parallel adaptive equalization outputs to a serial output.

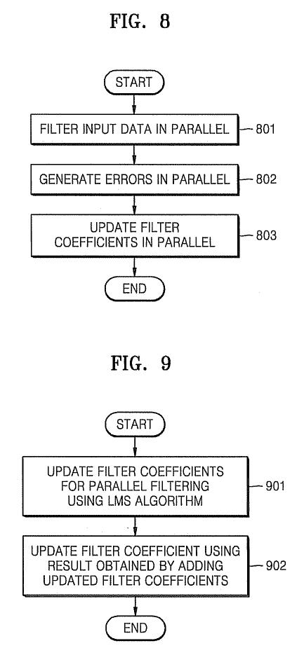

FIG. 8 is a flowchart illustrating an adaptive equalization method according to another embodiment of the present invention. As shown in FIG. 8, parallel input data is filtered in parallel in operation 801. That is, similar to the first through nth filters 310_1 through 310_{—}n illustrated in FIG. 3, first through nth input data is filtered in an n-parallel structure.

Errors between the parallel-filtered results and a pre-set reference value are generated in parallel in operation 802. That is, similar to the operation of the first through nth error generation units 320_1 through 320_{—}n illustrated in FIG. 3, the differences between the parallel input filtering results and the pre-set reference value are detected, and the differences are generated in parallel. The differences are errors between the parallel filtered results and the pre-set reference value.

Filter coefficient values are updated in parallel in operation 803 using the parallel generated errors and the first through nth input data before the parallel filtering is performed. The process of updating the filter coefficient values in parallel may be performed as illustrated in FIG. 9. As shown in FIG. 9, similar to the first filter coefficient update part 501 illustrated in FIG. 5, filter coefficient values for the parallel filtering are updated in operation 901 by applying the LMS algorithm to the errors generated in parallel and the first through nth input data before the parallel filtering operation is performed.

Similar to the second filter coefficient update part 502 illustrated in FIG. 5, the updated filter coefficient values are added using at least one adding process, and the filter coefficient values are updated using the result of the addition. If an initial filter coefficient value used in operation 901 is not set to 1/n of an initial filter coefficient value of a serial structure, operation 902 further includes dividing the adding result by n and updating a filter coefficient value of a corresponding filter using the division result.

As shown in FIG. 8, the filtering (801) operation, the parallel generation of errors (802), and the parallel updating of filter coefficient values (803) are each performed using n-divided clock signals having different phases.

The invention can also be embodied as computer readable code on a computer readable recording medium. The computer readable recording medium is any data storage device that can store data which can be thereafter read by a computer system. Examples of the computer readable recording medium include read-only memory (ROM), random-access memory (RAM), CD-ROMs, magnetic tapes, floppy disks, optical data storage devices, and carrier waves (such as data transmission through the Internet). The computer readable recording medium can also be distributed over network coupled computer systems so that the computer readable code is stored and executed in a distributed fashion.

As is described above, according to aspects of the present invention, the processing speed of an adaptive equalizer can be increased by implementing a parallel structure in which the adaptive equalizer operates using n-divided clock signals having different phases all over the entire duration when adaptive equalization using an LMS algorithm is performed. In addition, by updating a filter coefficient of each filter based on a result obtained by adding all filter coefficient values updated according to n filters (or paths) having a parallel structure, filter coefficients of filters having the parallel structure can be correctly updated.

According to aspects of the invention, the present invention may be implemented to update a filter coefficient of each filter based on a result obtained by adding filter coefficient values of n paths when filter coefficients are updated in an adaptive equalizer having an n-parallel filter structure.

Although a few embodiments of the present invention have been shown and described, it would be appreciated by those skilled in the art that changes may be made in these embodiments without departing from the principles and spirit of the invention, the scope of which is defined in the claims and their equivalents.

What is claimed is:

1. An adaptive equalizer comprising:
n filters in parallel with one another to output signals filtered from an input data;
n error generation units, in parallel with one another, to respectively generate errors with respect to the signals output from the n filters;
n filter coefficient update units, in parallel with one another, to respectively update filter coefficients of the n filters using the errors output from the n error generation units and the data input to the n filters; and
a clock divider to divide a clock signal by n and to provide the n-divided clock signals having different phases to the n filters, the n error generation units, and the n filter coefficient update units, wherein n is a natural number equal to or greater than 2.

2. The adaptive equalizer of claim 1, wherein each of the n filter coefficient update units comprises:
a first filter coefficient update part to update the filter coefficients of the n filters using errors output from the n error generation units and data input to the n filters, respectively; and
a second filter coefficient update unit to update a filter coefficient of a corresponding filter among the n filters using a result obtained by the addition of the updated filter coefficients of the n filters, wherein, if the number of taps of the corresponding filter is i, the filter coefficient update unit comprises i first filter coefficient update parts and i second filter coefficient update parts.

3. The adaptive equalizer of claim 2, wherein the first filter coefficient update part updates the filter coefficients of the n filters by applying a Least Mean Square (LMS) algorithm to the errors with respect to the n filters and the data input to the n filters.

4. The adaptive equalizer of claim 3, wherein the second filter coefficient update part adds the updated filter coefficients of the n filters using at least one addition operation.

5. The adaptive equalizer of claim 2, wherein the second filter coefficient update part adds the updated filter coefficients of the n filters using the at least one addition operation.

6. The adaptive equalizer of claim 2, wherein the second filter coefficient update part comprises a divider to divide a result of the addition by n and to update the filter coefficient of the corresponding filter using a result of the division.

7. The adaptive equalizer of claim 2, wherein an initial filter coefficient value used by the first filter coefficient update part is set to 1/n of an initial filter coefficient value of a serial structure.

8. An adaptive equalization method comprising:
parallel-filtering input data;
parallel-generating errors between the respective parallel-filtered results and a reference value; and
parallel-updating filter coefficients using the parallel-generated errors and the input data before the parallel-filtering is performed, wherein each of the parallel-filtering, the parallel-generating, and the parallel-updating is performed using n-divided clock signals having different phases.

9. The adaptive equalization method of claim 8, wherein the parallel-updating of the filter coefficients comprises:
respectively updating the filter coefficients for the parallel-filtering by applying a Least Mean Square (LMS) algorithm to the parallel-generated errors and the data input before the parallel-filtering is performed; and
adding the updated filter coefficients for the parallel-filtering using at least one adding process and updating a corresponding filter coefficient using the adding result.

10. The adaptive equalization method of claim 9, wherein an initial filter coefficient value used in the updating of the filter coefficients for the parallel-filtering is set to 1/n of an initial filter coefficient value of a serial structure.

11. The adaptive equalization method of claim 9, wherein the updating of the corresponding filter coefficient using a result of the addition further comprises dividing the result of the addition by n and updating the corresponding filter coefficient using the division result.

12. An adaptive equalizer comprising:
n filters, in parallel with one another, to output signals filtered from an input data to which a first set of n-divided clock signals are provided;
n error generation units, in parallel with one another, to respectively generate error signals with respect to the signals output from the n filters to which a second set of n-divided clock signals are provided; and
n filter coefficient update units, in parallel with one another, to respectively update filter coefficients of the n filters, to which a third set of n-divided clock signals are provided, using the error signal output from the n error generation units and the data input to the n filters.

13. An adaptive equalization method comprising:
parallel filtering input data;
generating errors with respect to the filtered input data in parallel; and
updating filter coefficients in accordance with the generated errors in parallel.

14. The method according to claim 13, wherein data of first through nth filters are filtered in an n-parallel structure.

15. The method according to claim 13, wherein the generating of the errors comprises:
detecting the differences between the parallel input filtering results and a pre-set reference value; and
generating the differences in parallel.

16. The method according to claim 13, further comprising:
updating the filter coefficients for parallel filtering using least mean square (LMS) algorithm; and
updating the filter coefficients using a result of an addition of the updated filter coefficients.
